(19) United States
(12) Patent Application Publication
(10) Pub. No.: US 2025/0138422 A1
(43) Pub. Date: May 1, 2025

(54) PHOTOSENSITIVE RESIN COMPOSITION, MANUFACTURING METHOD OF ELECTRONIC DEVICE, AND ELECTRONIC DEVICE

(71) Applicant: SUMITOMO BAKELITE CO., LTD., Tokyo (JP)

(72) Inventors: Takuji KAWANAMI, Tokyo (JP); Yuma TANAKA, Tokyo (JP); Ritsuya KAWASAKI, Tokyo (JP)

(73) Assignee: SUMITOMO BAKELITE CO., LTD., Tokyo (JP)

(21) Appl. No.: 18/683,961

(22) PCT Filed: Aug. 20, 2021
(86) PCT No.: PCT/JP2021/030570

§ 371 Date: Feb. 15, 2024

(51) Int. Cl. G03F 7/037; C08F 2/50; C08F 222/10; C08G 73/10; G03F 7/028

(52) U.S. Cl. CPC G03F 7/037; C08F 2/50; C08F 222/105; C08G 73/1007; C08G 73/1039; C08G 73/1071; G03F 7/028

(57) ABSTRACT

Provided is a photosensitive resin composition containing a polyamide resin and/or a polyimide resin, in which, in a case where a cured film obtained by heating the photosensitive resin composition at 170° C. for 2 hours is subjected to a dynamic viscoelasticity measurement under the following conditions, a storage elastic modulus E′₂₂₀ at 220° C. is 0.5 to 3.0 GPa. [Conditions] Frequency: 1 Hz, Temperature: 30° C. to 300° C., heating rate: 5° C./min, Measurement mode: tensile mode

### TECHNICAL FIELD

The present invention relates to a photosensitive resin composition, a manufacturing method of an electronic device, and an electronic device. The present invention more specifically relates to a photosensitive resin composition containing a polyamide resin and/or a polyimide resin, a manufacturing method of an electronic device using the photosensitive resin composition, and an electronic device which can be manufactured using the manufacturing method of an electronic device.

### BACKGROUND ART

In electrical and electronic fields, a photosensitive resin composition containing a polyamide resin and/or a polyimide resin may be used to form a cured film such as an insulating layer. Therefore, the photosensitive resin composition containing a polyamide resin and/or a polyimide resin has been studied.

As an example, Patent Document 1 discloses a photosensitive composition containing: at least one fully imidized polyimide polymer having a weight-average molecular weight in a range of approximately 20,000 Daltons to approximately 70,000 Daltons; at least one solubility switching compound; at least one photoinitiator; and at least one solvent, in which the photosensitive composition is capable of forming a film having a dissolution rate of more than approximately 0.15 μm/sec in a case where cyclopentanone is used as a developer.

Patent Documents 2 and 3, and the like also discloses a photosensitive resin composition containing a polyamide resin and/or a polyimide resin.

### RELATED DOCUMENT

### Patent Document

[Patent Document 1] International Publication No. WO2016-172092
[Patent Document 2] International Publication No. 2007/047384
[Patent Document 3] Japanese Unexamined Patent Publication No. 2018-070829

### SUMMARY OF THE INVENTION

### Technical Problem

As an electronic device is more sophisticated and complex, reliability higher than or equal to the related art has been required for the electronic device. Therefore, it has been required to improve the reliability of the electronic device by improving the cured film (improving the photosensitive resin composition for forming the cured film).

In addition, in recent years, in order to reduce thermal damage on semiconductor chips, it has been required to relatively lower a heating temperature (for example, to be approximately 170° C.) at the time of forming the cured film.

The present invention has been made in view of such circumstances. An object of the present invention is to provide a photosensitive resin composition capable of manufacturing an electronic device having high reliability by curing the photosensitive resin composition by heating at approximately 170° C. to form a cured film.

### Solution to Problem

The present inventors have completed the present invention provided below and have accomplished the object.

According to the present invention, the following photosensitive resin composition is provided.

The photosensitive resin composition is a photosensitive resin composition containing a polyamide resin and/or a polyimide resin,
in which, in a case where a cured film obtained by heating the photosensitive resin composition at 170° C. for 2 hours is subjected to a dynamic viscoelasticity measurement under the following conditions, a storage elastic modulus E′₂₂₀ at 220° C. is 0.5 to 3.0 GPa.

### [Conditions]

Frequency: 1 Hz
Temperature: 30° C. to 300° C.
Heating rate: 5° C./min
Measurement mode: tensile mode

In addition, according to the present invention,
a manufacturing method of an electronic device, including a film forming step of forming a photosensitive resin film over a substrate using the above-described photosensitive resin composition,
an exposure step of exposing the photosensitive resin film, and
a development step of developing the exposed photosensitive resin film,
is provided.

In addition, according to the present invention,
an electronic device including a cured film of the above-described photosensitive resin composition
is provided.

### Advantageous Effects of Invention

By curing the photosensitive resin composition according to the aspect of the present invention by heating at approximately 170° C. to form a cured film, it is possible to manufacture an electronic device having high reliability.

### BRIEF DESCRIPTION OF THE DRAWINGS

FIGS. 1(a), 1(b), and 1(c) are views for explaining a manufacturing method of an electronic device.

FIGS. 2(a), 2(b), and 2(c) are views for explaining the manufacturing method of an electronic device.

FIGS. 3(a), 3(b), and 3(c) are views for explaining the manufacturing method of an electronic device.

### DESCRIPTION OF EMBODIMENTS

Hereinafter, embodiments of the present invention will be described in detail with reference to the drawings.

In all drawings, the same constituents are designated by the same reference numerals, and description thereof will not be repeated.

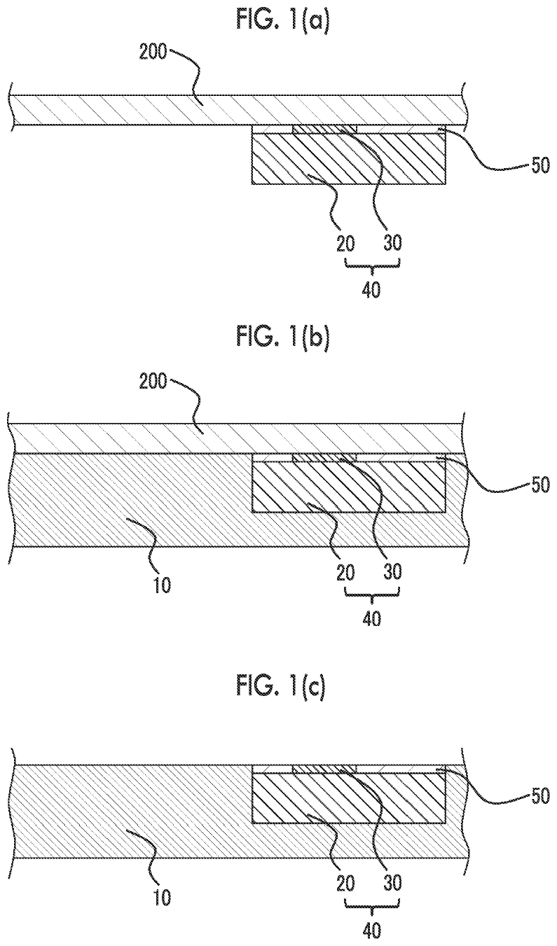

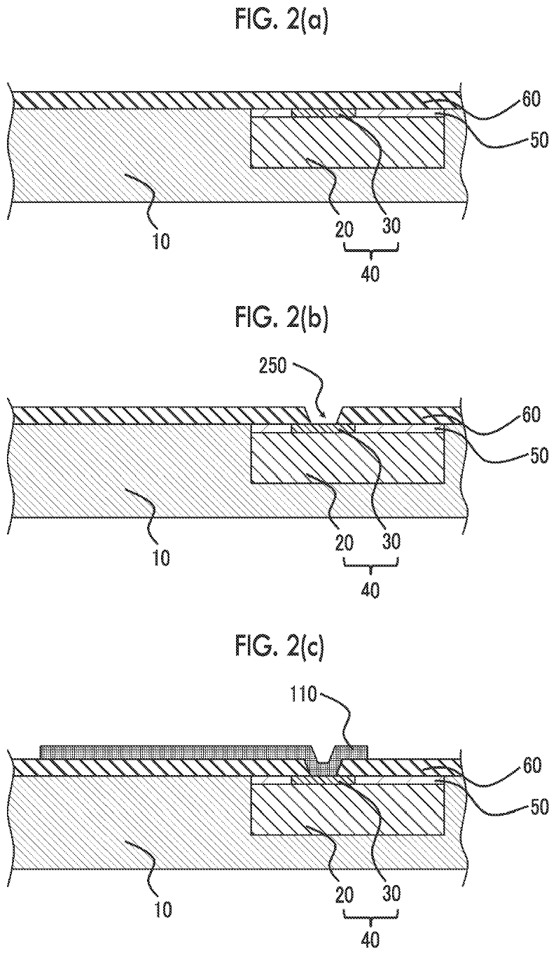

In order to avoid complication, (i) in a case where there are a plurality of the same constituents in the same drawing, only one of them is coded, and in a case where all constituents are not coded, or (ii) particularly in FIG. 2(a) and later, the same constituents as in FIGS. 1(a) and 1(b) may not be re-coded.

All drawings are for illustration purposes only. A shape and dimensional ratio of each member in the drawings do not necessarily correspond to the actual article.

In the present specification, a term “substantially” means to include a range in consideration of manufacturing tolerances, assembly variations, and the like, unless otherwise specified explicitly.

In the present specification, a notation “X to Y” in a description of a numerical range means equal to or more than X and equal to or less than Y unless otherwise specified. For example, “1% to 5% by mass” means “equal to or more than 1% by mass and equal to or less than 5% by mass”.

In a notation of a group (atomic group) in the present specification, a notation which does not indicate whether it is substituted or unsubstituted includes both those having no substituent and those having a substituent. For example, an “alkyl group” includes not only an alkyl group having no substituent (unsubstituted alkyl group) but also an alkyl group having a substituent (substituted alkyl group).

A notation “(meth)acryl” in the present specification represents a concept including both acryl and methacryl. The same applies to similar notations such as “(meth)acrylate”.

Unless otherwise specified, a term “organic group” in the present specification means an atomic group obtained by removing one or more hydrogen atoms from an organic compound. For example, a “monovalent organic group” represents an atomic group obtained by removing one hydrogen atom from any organic compound.

A term “electronic device” in the present specification is used as a meaning including an element, a device, a final product, and the like, to which electronic engineering technology has been applied, such as a semiconductor chip, a semiconductor element, a printed wiring board, an electric circuit display device, an information communication terminal, a light emitting diode, a physical battery, and a chemical battery.

### <Photosensitive Resin Composition>

The photosensitive resin composition according to the present embodiment contains a polyamide resin and/or a polyimide resin.

In a case where a cured film obtained by heating the photosensitive resin composition according to the present embodiment at 170° C. for 2 hours is subjected to a dynamic viscoelasticity measurement under the following conditions, a storage elastic modulus E′₂₂₀ at 220° C. is 0.5 to 3.0 GPa.

### [Conditions]

Frequency: 1 Hz
Temperature: 30° C. to 300° C.
Heating rate: 5° C./min
Measurement mode: tensile mode

In a manufacturing process of an electronic device, various “heating” may be carried out to increase a temperature of the cured film.

The present inventors consider that a high temperature caused by heating adversely affects the cured film in the electronic device, resulting in deterioration of reliability of the electronic device. More specifically, since the cured film is modified or softened at the high temperature, for example, it is considered that adhesive force between the cured film and a substrate decreases, causing peeling of the cured film to occur, which may result in reduced reliability of the electronic device.

Based on the consideration, the present inventors consider that, for example, in a case where it is possible to design a photosensitive resin composition capable of forming a cured film that is unlikely to be softened at 220° C. which can be adopted as a heating temperature in heating such as a reflow step (it can also be expressed as that an elastic modulus at 220° C. is relatively large), the decrease in adhesive force of the cured film due to heating may be reduced, resulting in high reliability of the electronic device. In addition, it is considered that, in a case where such a cured film can be formed by heating at approximately 170° C., it may be possible to follow the recent trend in the manufacturing of the electronic device.

Furthermore, based on the consideration, the present inventors have newly designed a photosensitive resin composition in which, in a photosensitive resin composition containing a polyamide resin and/or a polyimide resin, (i) a storage elastic modulus E′₂₂₀ of the cured film at 220° C. is adopted as an indicator of being difficult to soften the cured film at 220° C., and (ii) the E′₂₂₀ is 0.5 GPa or more. Here, as conditions for forming the cured film, “at 170° C. for 2 hours” is adopted in consideration of the recent trend in the manufacturing of the electronic device.

By applying the new photosensitive resin composition to the manufacturing of the electronic device (for example, formation of an insulating layer in the electronic device, and the like), the present inventors have succeeded in increasing the reliability of the electronic device.

Incidentally, in principle, it is considered that a larger E′₂₂₀ is better. However, from the viewpoint of cost and practical composition design, the upper limit of the E′₂₂₀ is set to 3.0 GPa in the present embodiment.

The E′₂₂₀ may be 0.5 to 3.0 GPa, and is preferably 0.6 to 2.5 GPa and more preferably 0.7 to 2.0 GPa.

The photosensitive resin composition according to the present embodiment, in which the E′₂₂₀ is 0.5 GPa or more and 3.0 GPa or less, can be produced by appropriately selecting materials, compositions, preparation methods, and the like.

Preferred materials for producing the photosensitive resin composition according to the present embodiment will be described below, and for example, as components used in combination with the polyamide resin and/or the polyimide resin, selecting an appropriate polyfunctional (meth)acrylate is exemplified.

Description of the photosensitive resin composition according to the present embodiment will be continued.

(Polyamide Resin and/or Polyimide Resin)

The photosensitive resin composition according to the present embodiment contains a polyamide resin and/or a polyimide resin. As long as the E′₂₂₀ is 0.5 to 3.0 GPa, structures, molecular weights, amounts used, and the like of the polyamide resin and/or the polyimide resin are not limited.

From the viewpoint of further reducing a shrinkage amount during curing, the photosensitive resin composition according to the present embodiment preferably contains a polyimide resin, and more preferably contains a polyimide resin having an imide ring structure.

In a case where the number of moles of imide groups included in the polyimide resin is denoted as IM and the number of moles of amide groups included in the polyimide resin is denoted as AM, an imidization ratio represented by {IM/(IM+AM)}×100(%) is preferably 90% or more, more preferably 95% or more, and still more preferably 98% or more. In short, it is preferable that the polyimide resin is a resin having no or few ring-opening amide structures and many ring-closed imide structures. By using such a polyimide resin, shrinkage (curing shrinkage) by heating can be further suppressed (because dehydration due to a ring closure reaction does not occur). As a result, it is possible to further improve the reliability of the electronic device, farther improve flatness of the cared film, and the like.

The imidization ratio can be known, for example, from an area of peaks corresponding to the amide group or an area of peaks corresponding to the imide group in an NMR spectrum. As another example, the imidization ratio can be known from an area of peaks corresponding to the amide group or an area or peaks corresponding to the imide group in an infrared absorption spectrum.

The polyamide resin and/or the polyimide resin preferably includes a fluorine atom. According to findings of the present inventors, the polyamide resin and/or the polyimide resin including a fluorine atom tends to have favorable organic solvent solubility than those not including a fluorine atom. Therefore, by using the polyamide resin and/or the polyimide resin including a fluorine atom, properties of the photosensitive resin composition can be easily formed into a varnish.

An amount (mass ratio) of fluorine atoms in the polyamide resin and/or the polyimide resin including a fluorine atom is, for example, 1% to 30% by mass, preferably 3% to 28% by mass and more preferably 5% to 25% by mass. In a case where a large amount of fluorine atoms is included in the resin, sufficient organic solvent solubility is likely to be obtained. On the other hand, from the viewpoint of balance with other performances, it is preferable that the amount of fluorine atoms is not too large.

By designing various terminals of the polyamide resin and/or the polyimide resin, for example, mechanical properties (tensile elongation and the like) of the cured product can be further improved.

As an example, the polyamide resin and/or the polyimide resin preferably has, at the terminal thereof, a group capable of forming a bond by reacting with an epoxy group. Examples of such a group include an acid anhydride group, a hydroxy group, an amino group, and a carboxy group.

It is preferable that the polyamide resin and/or the polyimide resin has an acid anhydride group at the terminal thereof. In the photosensitive resin composition according to the present embodiment, the acid anhydride group and the epoxy group are sufficiently easy to form a bond.

The acid anhydride group is preferably a group having an acid anhydride skeleton of a cyclic structure. The “cyclic structure” here is preferably a 5-membered ring or a 6-membered ring, and more preferably a 5-membered ring.

With regard to the terminal structure, it is preferable that the polyamide resin and/or the polyimide resin does not have a maleimide structure at the terminal thereof.

The polyamide resin preferably includes a structural unit represented by General Formula (PA-1).

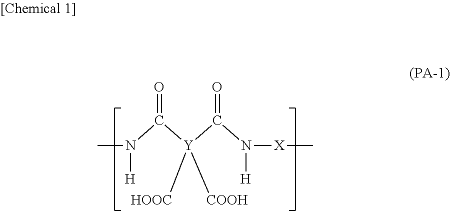

The polyimide resin preferably includes a structural unit represented by General Formula (PI-1).

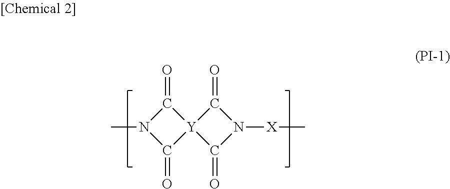

In General Formulae (PA-1) and (PI-1),
X is a divalent organic group, and
Y is a tetravalent organic group.

In General Formulae (PA-1) and (PI-1), at least one of X or Y is preferably a fluorine atom-containing group. From the viewpoint of organic solvent solubility, in General Formulae (PA-1) and (PI-1), both X and Y are preferably fluorine atom-containing groups.

In General Formulae (PA-1) and (PI-1), the divalent organic group of X and/or the tetravalent organic group of Y preferably includes an aromatic ring structure, and more preferably includes a benzene ring structure. As a result, heat resistance tends to be further improved. The benzene ring here may be substituted with a fluorine atom or a fluorine atom-containing group such as a fluorinated alkyl group (preferably a trifluoromethyl group), or may be substituted with another group.

The divalent organic group of X and/or the tetravalent organic group of Y in General Formulae (PA-1) and (PI-1) preferably has a structure in which two to six benzene rings are bonded to each other through a single bond or a divalent linking group. Examples of the divalent linking group here include an alkylene group, a fluorinated alkylene group, and an ether group. The alkylene group and the fluorinated alkylene group may be linear or branched.

In General Formulae (PA-1) and (PI-1), the number of carbon atoms in the divalent organic group of X is, for example, 6 to 30.

In General Formulae (PA-1) and (PI-1), the number of carbon atoms in the tetravalent organic group of Y is, for example, 6 to 20.

Each of two imide rings in General Formula (PI-1) is preferably a 5-membered ring.

The polyamide resin more preferably includes a structural unit represented by General Formula (PA-2).

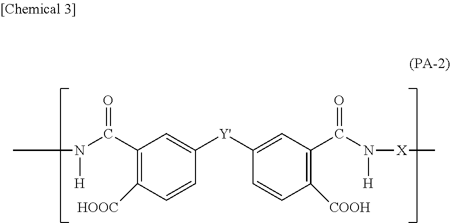

The polyimide resin more preferably includes a structural unit represented by General Formula (PI-2).

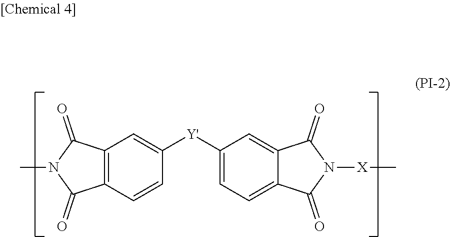

In General Formulae (PA-2) and (PI-2),
X has the same meaning as X in General Formulae (PA-1) and (PI-1), and
Y′ represents a single bond or an alkylene group.

Specific aspects of X are the same as those described in General Formulae (PA-1) and (PI-1).

The alkylene group of Y′ may be linear or branched. It is preferable that a part or all of hydrogen atoms in the alkylene group of Y′ is substituted with a fluorine atom. The number of carbon atoms in the alkylene group of Y′ is, for example, 1 to 6, preferably 1 to 4 and more preferably 1 to 3.

Typically, the polyamide resin can be obtained by a reaction (polycondensation) of a diamine and an acid dianhydride. The polyimide resin can be obtained by imidizing the polyamide resin (allowing a ring closure reaction). In addition, a desired functional group may be introduced into the polymer terminal as necessary. For specific reaction conditions, Examples described later, the description of Patent Document described above, and the like can be referred to.

In the finally obtained polyamide resin and/or polyimide resin, the diamine is incorporated into the polymer as the divalent organic group X in General Formula (PA-1) or (PI-1). In addition, the acid dianhydride is incorporated into the polymer as the tetravalent organic group Y in General Formula (PA-1) or (PI-1).

In the synthesis of the polyamide resin and/or the polyimide resin, one or two or more diamines can be used, and one or two or more acid dianhydrides can be used.

Examples of the diamine as the raw material include 3,4′-diaminodiphenyl ether (3,4′-ODA), 4,4′-diamino-2,2′-bis(trifluoromethyl)biphenyl (TFMB), 3,3′, 5,5′-tetramethylbenzidine, 2,3,5,6-tetramethyl-1,4-phenylenediamine, 3,3′-diaminodiphenylsulfone, 3,3′-dimethylbenzidine, 3,3′-bis(trifluoromethyl)benzidine, 2,2′-bis(p-aminophenyl)hexafluoropropane, bis(trifluoromethoxy)benzidine (TFMOB), 2,2′-bis(pentafluoroethoxy)benzidine (TFEOB), 2,2′-trifluoromethyl-4,4′-oxydianiline (OBABTF), 2-phenyl-2-trifluoromethyl-bis(p-aminophenyl)methane, 2-phenyl-2-trifluoromethyl-bis(m-aminophenyl)methane, 2,2′-bis(2-heptafluoroisopropoxy-tetrafluoroethoxy)benzidine (DFPOB), 2,2-bis(m-aminophenyl)hexafluoropropane (6-FmDA), 2,2-bis(3-amino-4-methylphenyl)hexafluoropropane, 3,6-bis(trifluoromethyl)-1,4-diaminobenzene (2TFMPDA), 1-(3,5-diaminophenyl)-2,2-bis(trifluoromethyl)-3,3,4,4,5,5,5-heptafluoropentane, 3,5-diaminobenzotrifluoride (3,5-DABTF), 3,5-diamino-5-(pentafluoroethyl)benzene, 3,5-diamino-5-(heptafluoropropyl)benzene, 2,2′-dimethylbenzidine (DMBZ), 2,2′, 6,6′-tetramethylbenzidine (TMBZ), 3,6-diamino-9,9-bis(trifluoromethyl)xanthene (6FCDAM), 3,6-diamino-9-trifluoromethyl-9-phenylxanthene (3FCDAM), and 3,6-diamino-9,9-diphenylxanthene.

Examples of the acid dianhydride as the raw material include pyromellitic anhydride (PMDA), diphenyl ether-3,3′, 4,4′-tetracarboxylic dianhydride (ODPA), benzophenone-3,3′,4,4′-tetracarboxylic dianhydride (BTDA), biphenyl-3,3′,4,4′-tetracarboxylic dianhydride (BPDA), diphenylsulfone-3,3′, 4,4′-tetracarboxylic dianhydride (DSDA), diphenylmethane-3,3′, 4,4′-tetracarboxylic dianhydride, 2,2-bis(3,4-phthalic anhydride)propane, and 2,2-bis(3,4-phthalic anhydride)-1,1,1,3,3,3-hexafluoropropane (6FDA). Needless to say, the acid dianhydride which can be used is not limited to these. One kind or two or more kinds of acid dianhydrides can be used.

A used ratio of the diamine and the acid dianhydride is basically 1:1 in terms of molar ratio. However, one thereof may be excessively used to obtain a desired terminal structure. Specifically, by using the diamine in an excessive amount, terminals (both terminals) of the polyamide resin and/or the polyimide resin are likely to be amino groups. On the other hand, by using the acid dianhydride in an excessive amount, terminals (both terminals) of the polyamide resin and/or the polyimide resin are likely to be acid anhydride groups. As described above, in the present embodiment, it is preferable that the polyamide resin and/or the polyimide resin has an acid anhydride group at the terminal thereof. Therefore, in the present embodiment, it is preferable to use an excessive amount of the acid dianhydride at the time of synthesizing the polyamide resin and/or the polyimide resin.

The resin terminal may have a desired functional group by reacting any reagent with the amino group and/or the acid anhydride group at the terminal of the polyamide resin and/or the polyimide resin, which is obtained by the polycondensation.

A weight-average molecular weight of the polyamide resin and/or the polyimide resin is, for example, 5,000 to 100,000, preferably 7,000 to 75,000 and more preferably 10,000 to 50,000. By setting the weight-average molecular weight of the polyamide resin and/or the polyimide resin to some extent, for example, sufficient heat resistance of the cured film can be obtained. In addition, in a case where the weight-average molecular weight of the polyamide resin and/or the polyimide resin is not too large, the polyamide resin and/or the polyimide resin can be easily dissolved in an organic solvent.

The weight-average molecular weight can be usually determined by a gel permeation chromatography (GPC) method using polystyrene as a standard substance.

### (Polyfunctional (Meth)Acrylate Compound)

The photosensitive resin composition according to the present embodiment preferably contains a polyfunctional (meth)acrylate compound. The polyfunctional (meth)acrylate compound is not particularly limited, and examples thereof include a compound having two or more (meth)acryloyl groups in one molecule.

According to findings of the present inventors, by using the polyamide resin and/or the polyimide resin in combination with the polyfunctional (meth)acrylate compound, it is easy to design the photosensitive resin composition in which the E′₂₂₀ is 0.5 to 3.0 GPa, and the performance of the cured film tends to be even better.

Although the details are not clear, it is considered that, in a case where the polyfunctional (meth)acrylate compound is cured (polymerized), a structure which is complicatedly “entangled” with the polyamide resin and/or the polyimide resin is formed. In particular, it is presumed that, through a polymerization, the polyfunctional (meth)acrylate compound forms a network structure which “includes” a cyclic skeleton of the polyimide resin having a cyclic skeleton such as an imide ring, or of the polyamide resin which can have a cyclic skeleton in a case where at least a part of a polyamide structure is ring-closed by heat. It is presumed that, by forming such a complicatedly entangled structure, the E′₂₂₀ is set to 0.5 to 3.0 GPa and the performance of the cured film is improved.

From the viewpoint of achieving the entangled structure described above or from the viewpoint of obtaining a cured film having high durability and favorable chemical resistance, the polyfunctional (meth)acrylate compound preferably has a tri- or higher functional group. Although there is no particular upper limit of the number of functional groups of the polyfunctional (meth)acrylate compound, the upper limit of the number of functional groups is, for example, 11 functional groups due to ease of obtaining the raw material.

As a general tendency, in a case where a polyfunctional (meth)acrylate compound having a large number of functional groups ((meth)acryloyl groups) is used, the chemical resistance of the cured film tends to increase. On the other hand, in a case where a polyfunctional (meth)acrylate compound having a small number of functional groups ((meth)acryloyl groups) is used, mechanical properties of the cured film, such as tensile elongation, tend to be favorable.

As an example, the polyfunctional (meth)acrylate compound preferably includes a 7- or higher functional (meth)acrylate compound.

As an example, the polyfunctional (meth)acrylate compound preferably includes a 5- or 6-functional (meth)acrylate compound.

As an example, the polyfunctional (meth)acrylate compound preferably includes a 3- or 4-functional (meth)acrylate compound.

As an example, the polyfunctional (meth)acrylate compound can include a compound represented by the following general formula. In the following general formula, R′ is a hydrogen atom or a methyl group, n is 0 to 3, and R is a hydrogen atom or a (meth)acryloyl group. A plurality of R's may be the same or different from each other.

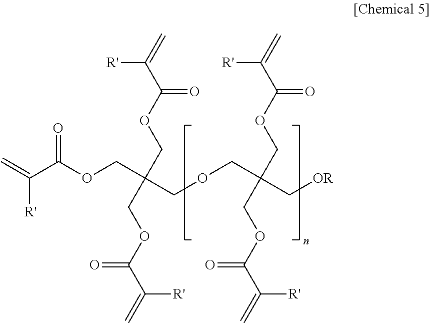

Specific examples of the polyfunctional (meth)acrylate compound include the following compounds. Needless to say, the polyfunctional (meth)acrylate compound is not limited to these.

Polyol polyacrylates such as ethylene glycol di(meth)acrylate, trimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, and dipentaerythritol hexa(meth)acrylate; epoxy acrylates such as di(meth)acrylate of bisphenol A diglycidyl ether and di(meth)acrylate of hexanediol diglycidyl ether; and urethane (meth)acrylates obtained by a reaction of hydroxyl group-containing (meth)acrylate such as polyisocyanate and hydroxyethyl (meth)acrylate.

Commercially available products such as ARONIX M-400, ARONIX M-460, ARONIX M-402, ARONIX M-510, and ARONIX M-520 (manufactured by Toagosei Co., Ltd.), KAYARAD T-1420, KAYARAD DPHA, KAYARAD DPCA20, KAYARAD DPCA30, KAYARAD DPCA60, and KAYARAD DPCA120 (manufactured by Nippon Kayaku Co., Ltd.), VISCOAT #230, VISCOAT #300, VISCOAT #802, VISCOAT #2500, VISCOAT #1000, and VISCOAT #1080 (manufactured by OSAKA ORGANIC CHEMICAL INDUSTRY LTD.), and NK ESTER A-BPE-10, NK ESTER A-GLY-9E, NK ESTER A-9550, and NK ESTER A-DPH (manufactured by SHIN-NAKAMURA CHEMICAL CO, LTD.)

In a case where the photosensitive resin composition contains a polyfunctional (meth)acrylate compound, it may contain only one polyfunctional (meth)acrylate compound or may contain two or more polyfunctional (meth)acrylate compounds. In the latter case, it is preferable to use polyfunctional (meth)acrylate compounds having different numbers of functional groups in combination. It is considered that, by using polyfunctional (meth)acrylate compounds having different numbers of functional groups in combination, a more complex “entangled structure” can be formed, and properties of the cured film are further improved.

Incidentally, among commercially available polyfunctional (meth)acrylate compounds, there is a mixture of (meth)acrylates having different numbers of functional groups.

In a case of using the polyfunctional (meth)acrylate compound, an amount of the polyfunctional (meth)acrylate compound with respect to 100 parts by mass of the polyamide resin and/or the polyimide resin is preferably 50 to 200 parts by mass and more preferably 60 to 150 parts by mass.

The amount of the polyfunctional (meth)acrylate compound used is not particularly limited, but by appropriately adjusting the amount used as described above, one or two or more of the various performances can be further enhanced. As described above, in the photosensitive resin composition according to the present embodiment, it is considered that the “entangled structure” of the polyamide resin and/or the polyimide resin and the polyfunctional (meth)acrylate is formed by curing, but by appropriately adjusting the amount of the polyfunctional (meth)acrylate compound used with respect to the polyamide resin and/or the polyimide resin, it is considered that the polyamide resin and/or the polyimide resin and the polyfunctional (meth)acrylate compound are appropriately entangled, and the amount of excess components which do not participate in the entanglement is reduced. Therefore, it is considered that the performance is further improved.

### (Photosensitizing Agent)

The photosensitive resin composition according to the present embodiment preferably contains a photosensitizing agent. The photosensitizing agent is not particularly limited as long as it can generate active species by light to cure the photosensitive resin composition.

The photosensitizing agent preferably includes a photoradical generator. The photoradical generator is particularly effective for polymerizing the polyfunctional (meth)acrylate compound.

The photoradical generator which can be used is not particularly limited, and a known photoradical generator can be appropriately used.

Examples thereof include alkylphenone-based compounds such as 2,2-diethoxyacetophenone, 2,2-dimethoxy-2-phenylacetophenone, 1-hydroxycyclohexylphenylketone, 2-hydroxy-2-methyl-1-phenylpropan-1-one, 1-[4-(2-hydroxyethoxy)phenyl]-2-hydroxy-2-methyl-1-propan-1-one, 2-hydroxy-l-{4-[4-(2-hydroxy-2-methylpropionyl)benzyl]phenyl}-2-methylpropan-1-one, 2-methyl-1-(4-methylthiophenyl)-2-morpholinopropan-1-one, and 2-benzyl-2-dimethylamino-1-(4-morpholinophenyl)-butanone-1,2-(dimethylamino)-2-[(4-methylphenyl)methyl]-1-[4-(4-morpholinyl)phenyl]-1-butanone; benzophenone-based compounds such as benzophenone, 4,4′-bis(dimethylamino)benzophenone, and 2-carboxybenzophenone; benzoin-based compounds such as benzoin methyl ether, benzoin ethyl ether, benzoin isopropyl ether, and benzoin isobutyl ether; thioxanthone-based compounds such as thioxanthone, 2-ethylthioxanthone, 2-isopropylthioxanthone, 2-chlorothioxanthone, 2,4-dimethylthioxanthone, and 2,4-diethylthioxanthone; halomethylated triazine-based compounds such as 2-(4-methoxyphenyl)-4,6-bis(trichloromethyl)-s-triazine, 2-(4-methoxynaphthyl)-4,6-bis(trichloromethyl)-s-triazine, 2-(4-ethoxynaphthyl)-4,6-bis(trichloromethyl)-s-triazine, and 2-(4-ethoxycarboxynylnaphthyl)-4,6-bis(trichloromethyl)-s-triazine; halomethylated oxadiazole-based compounds such as 2-trichloromethyl-5-(2′-benzofuryl)-1,3,4-oxadiazole, 2-trichloromethyl-5-[(β-(2′-benzofuryl)vinyl]-1,3,4-oxadiazole, 4-oxadiazole, and 2-trichloromethyl-5-furyl-1,3,4-oxadiazole; biimidazole-based compounds such as 2,2′-bis(2-chlorophenyl)-4,4′, 5,5′-tetraphenyl-1,2′-biimidazole, 2,2′-bis(2,4-dichlorophenyl)-4,4′, 5,5′-tetraphenyl-1,2′-biimidazole, 2,2′-bis(2,4,6-trichlorophenyl)-4,4′, 5,5′-tetraphenyl-1, and 2′-biimidazole; oxime ester-based compounds such as 1,2-octanedione, 1-[4-(phenylthio)phenyl]-2-(O-benzoyloxime), ethanone, 1-[9-ethyl-6-(2-methylbenzoyl)-9H-carbazole-3-yl]-, and 1-(O-acetyloxime); titanocene-based compounds such as bis(η5-2,4-cyclopentadien-1-yl)-bis(2,6-difluoro-3-(1H-pyrrol-1-yl)-phenyl) titanium; benzoic acid ester-based compounds such as p-dimethylaminobenzoic acid and p-diethylaminobenzoic acid; and acridine-based compounds such as 9-phenylacridine. Among these, an oxime ester-based compound can be particularly preferably used.

In a case where the photosensitive resin composition contains a photosensitizing agent, the photosensitive resin composition may contain only one kind of photosensitizing agent or may contain two or more kinds thereof.

In a case of using the photosensitizing agent, an amount thereof used with respect to 100 parts by mass of the polyfunctional (meth)acrylate compound is, for example, 1 to 30 parts by mass, preferably 3 to 20 parts by mass.

(Thermal radical initiator) The photosensitive resin composition according to the present embodiment preferably contains a thermal radical initiator. By using the thermal radical initiator, a value of CTE2/CTE1, which will be described later, can be appropriately adjusted, the reliability of the electronic device can be further improved, and the heat resistance of the cured film can be further improved. It is considered that this is because the polymerization reaction of the polyfunctional (meth)acrylate compound is further promoted by using the thermal radical initiator.

The thermal radical initiator preferably includes an organic peroxide. Examples of the organic peroxide include octanoyl peroxide, lauroyl peroxide, stearoyl peroxide, 1,1,3,3-tetramethylbutylperoxy 2-ethylhexanoate, oxalic acid peroxide, 2,5-dimethyl-2,5-di(2-ethylhexanoylperoxy)hexane, 1-cyclohexyl-1-methylethylperoxy 2-ethylhexanoate, t-hexylperoxy 2-ethylhexanoate, t-butylperoxy 2-ethylhexanoate, m-tolyl peroxide, benzoyl peroxide, methyl ethyl ketone peroxide, acetyl peroxide, t-butyl hydroperoxide, di-t-butyl peroxide, cumene hydroperoxide, dicumyl peroxide, t-butyl perbenzoate, parachlorobenzoyl peroxide, and cyclohexanone peroxide.

In a case of using the thermal radical initiator, only one thermal radical initiator may be used, or two or more thermal radical initiators may be used.

In a case of using the thermal radical initiator, an amount thereof with respect to 100 parts by mass of the polyfunctional (meth)acrylate compound is preferably 0.1 to 30 parts by mass and more preferably 1 to 20 parts by mass.

### (Epoxy Resin)

The photosensitive resin composition according to the present embodiment preferably contains an epoxy resin. Although the details are not clear, it is considered that the epoxy resin reacts (bonds) with, for example, the polyamide resin and/or the polyimide resin. Probably due to flexibility of an ether structure formed by the reaction, the mechanical properties (tensile elongation and the like) of the cured film tend to be further improved.

As the epoxy resin, all compounds having one or more (preferably two or more) epoxy groups in one molecule can be appropriately used.

Specific examples of the epoxy resin include glycol esters such as n-butyl glycidyl ether, 2-ethoxyhexyl glycidyl ether, phenyl glycidyl ether, allyl glycidyl ether, ethylene glycol diglycidyl ether, propylene glycol diglycidyl ether, neopentyl glycol diglycidyl ether, glycerol polyglycidyl ether, sorbitol polyglycidyl ether, and glycidyl ether of bisphenol A (or F); glycidyl esters such as adipic acid diglycidyl ester and o-phthalic acid diglycidyl ester; alicyclic epoxy resins such as 3,4-epoxycyclohexylmethyl (3,4-epoxycyclohexane)carboxylate, 3,4-epoxy-6-methylcyclohexylmethyl (3,4-epoxy-6-methylcyclohexane)carboxylate, bis(3,4-epoxy-6-methylcyclohexylmethyl)adipate, dicyclopentanediene oxide, bis(2,3-epoxycyclopentyl)ether, CELLOXIDE 2021P, CELLOXIDE 2081, CELLOXIDE 2083, CELLOXIDE 2085, CELLOXIDE 8000, and EPOLIDE GT401 manufactured by Daicel Corporation; aliphatic polyglycidyl ethers such as 2,2′-((((1-(4-(2-(4-(oxiran-2-ylmethoxy)phenyl)propan-2-yl)phenyl)ethane-1,1-diyl)bis(4,1-phenylene))bis(oxy))bis(methylene))bis(oxirane)) (for example, Techmore VG3101L manufactured by Printec Co.), EPOLITE 100MF (manufactured by KYOEISHA CHEMICAL Co., LTD.), and Epiol TMP (manufactured by NOF CORPORATION); and 1,1,3,3,5,5-hexamethyl-1,5-bis(3-(oxiran-2-ylmethoxy)propyl)trisiloxane (for example, DMS-E09 (manufactured by Gelest Inc.)).

As the epoxy resin, an epoxy resin having two to four epoxy groups in one molecule is preferable, and an epoxy resin having two or three epoxy groups in one molecule is more preferable. By adjusting the number of functional groups in the epoxy resin, for example, the heat resistance of the cured film, the mechanical properties of the cured film, and the like can be easily improved in a well-balanced manner.

From another viewpoint, the epoxy resin is preferably an epoxy resin having an aromatic ring structure and/or an alicyclic structure. From the viewpoint of heat resistance, it is particularly preferable to use such an epoxy resin.

In a case of using the epoxy resin, only one epoxy resin may be used, or two or more epoxy resins may be used in combination.

In a case of using the epoxy resin, an amount thereof with respect to 100 parts by mass of the polyamide resin and/or the polyimide resin is, for example, 0.5 to 30 parts by mass, preferably 1 to 20 parts by mass and more preferably 3 to 15 parts by mass.

### (Curing Catalyst)

The photosensitive resin composition according to the present embodiment preferably contains a curing catalyst. The curing catalyst has a work of promoting the reaction of the epoxy resin. By using the curing catalyst, the reaction involving the epoxy resin proceeds sufficiently, and for example, a tensile elongation rate of the cured film can be further improved.

Examples of the curing catalyst include compounds known as a curing catalyst (also referred to as a curing accelerator) for the epoxy resin. Examples thereof include diazabicycloalkenes such as 1,8-diazabicyclo[5,4,0]undecene-7 and derivatives thereof; amine-based compounds such as tributylamine and benzyldimethylamine; imidazole compounds such as 2-methylimidazole; organic phosphines such as triphenylphosphine and methyldiphenylphosphine; tetra-substituted phosphonium salts such as tetraphenylphosphonium tetraphenylborate, tetraphenylphosphonium tetrabenzoic acid borate, tetraphenylphosphonium tetranaphthoic acid borate, tetraphenylphosphonium tetranaphthoyloxyborate, tetraphenylphosphonium tetranaphthyloxyborate, and tetraphenylphosphonium 4,4′-sulfonyl diphenolate; and triphenylphosphine adducted with benzoquinone. Among these, organic phosphines are preferable.

In a case of using the curing catalyst, an amount thereof with respect to 100 parts by mass of the epoxy resin is, for example, 1 to 80 parts by mass, preferably 5 to 50 parts by mass.

### (Silane Coupling Agent)

The photosensitive resin composition according to the present embodiment preferably contains a silane coupling agent. By using the silane coupling agent, for example, it is possible to further improve adhesiveness between the substrate and the cured film.

Examples of the silane coupling agent include silane coupling agents such as an amino group-containing silane coupling agent, an epoxy group-containing silane coupling agent, a (meth)acryloyl group-containing silane coupling agent, a mercapto group-containing silane coupling agent, a vinyl group-containing silane coupling agent, a ureido group-containing silane coupling agent, a sulfide group-containing silane coupling agent, and a silane coupling agent with a cyclic anhydride structure.

Examples of the amino group-containing silane coupling agent include bis(2-hydroxyethyl)-3-aminopropyltriethoxysilane, γ-aminopropyltriethoxysilane, γ-aminopropyltrimethoxysilane, γ-aminopropylmethyldiethoxysilane, γ-aminopropylmethyldimethoxysilane, N-β(aminoethyl) γ-aminopropyltrimethoxysilane, N-β(aminoethyl) γ-aminopropyltriethoxysilane, N-β(aminoethyl) γ-aminopropylmethyldimethoxysilane, N-β(aminoethyl) γ-aminopropylmethyldiethoxysilane, and N-phenyl-γ-amino-propyltrimethoxysilane.

Examples of the epoxy group-containing silane coupling agent include γ-glycidoxypropyltrimethoxysilane, γ-glycidoxypropylmethyldiethoxysilane, D-(3,4-epoxycyclohexyl)ethyltrimethoxysilane, and γ-glycidylpropyltrimethoxysilane.

Examples of the (meth)acryloyl group-containing silane coupling agent include γ-((meth)acryloyloxypropyl)trimethoxysilane, γ-((meth)acryloyloxypropyl)methyldimethoxysilane, and γ-((meth)acryloyloxypropyl)methyldiethoxysilane.

Examples of the mercapto group-containing silane coupling agent include 3-mercaptopropyltrimethoxysilane.

Examples of the vinyl group-containing silane coupling agent include vinyltris(β-methoxyethoxy)silane, vinyltriethoxysilane, and vinyltrimethoxysilane.

Examples of the ureido group-containing silane coupling agent include 3-ureidopropyltriethoxysilane.

Examples of the sulfide group-containing silane coupling agent include bis(3-(triethoxysilyl)propyl)disulfide and bis(3-(triethoxysilyl)propyl)tetrasulfide.

Examples of the silane coupling agent with a cyclic anhydride structure include 3-trimethoxysilylpropylsuccinic acid anhydride, 3-triethoxysilylpropylsuccinic acid anhydride, and 3-dimethylmethoxysilylpropylsuccinic acid anhydride.

In the present embodiment, the silane coupling agent with a cyclic anhydride structure is particularly preferably used. Although the details are not clear, it is presumed that the cyclic anhydride structure easily reacts with the main chain, the side chain, and/or the terminal of the polyamide resin and/or the polyimide resin, and thus a particularly favorable effect of improving the adhesiveness is obtained.

In a case of using the silane coupling agent, it may be used alone or in combination of two or more kinds of adhesion aids.

In a case of using the silane coupling agent, an amount thereof used with respect to 100 parts by mass of the amount of the polyamide resin and/or the polyimide resin used is, for example, 0.1 to 20 parts by mass, preferably 0.3 to 15 parts by mass, more preferably 0.4 to 12 parts by mass, and still more preferably 0.5 to 10 parts by mass.

### (Surfactant)

The photosensitive resin composition according to the present embodiment preferably contains a surfactant. With this, it is possible to further enhance coating properties of the photosensitive resin composition and the flatness of the film.

Examples of the surfactant include a fluorine-based surfactant, a silicone-based surfactant, an alkyl-based surfactant, and an acrylic surfactant.

The surfactant preferably includes a surfactant containing at least one of a fluorine atom or a silicon atom. As a result, in addition to obtaining a uniform resin film (improving coating properties) and improving developability, it also contributes to improving adhesion strength.

From another viewpoint, the surfactant is preferably nonionic. The use of nonionic surfactant is preferable, for example, from the viewpoint of suppressing an unintentional reaction with other components in the composition and enhancing storage stability of the composition.

Examples of a commercially available product which can be preferably used as the surfactant include surfactants having an oligomer structure containing fluorine, such as “MEGAFACE” series F-251, F-253, F-281, F-430, F-477, F-551, F-552, F-553, F-554, F-555, F-556, F-557, F-558, F-559, F-560, F-561, F-562, F-563, F-565, F-568, F-569, F-570, F-572, F-574, F-575, F-576, R-40, R-40-LM, R-41, and R-94 manufactured by DIC Corporation; fluorine-containing nonionic surfactants such as FTERGENT 250 and FTERGENT 251 manufactured by NEOS COMPANY LIMITED; and silicone-based surfactants such as SILFOAM (registered trademark) series (for example, SD 100 TS, SD 670, SD 850, SD 860, and SD 882) manufactured by Wacker Chemie AG.

In addition, examples of a preferred surfactant include FC4430 and FC4432 manufactured by 3M Co., Ltd.

In a case where the photosensitive resin composition according to the present embodiment contains a surfactant, one or two or more surfactants can be contained.

In a case where the photosensitive resin composition according to the present embodiment contains the surfactant, an amount thereof with respect to 100 parts by mass of the content of the polyamide resin and/or the polyimide resin is, for example, 0.001 to 1 part by mass, preferably 0.005 to 0.5 parts by mass.

### (Water)

The photosensitive resin composition according to the present embodiment may contain water. For example, the presence of water facilitates progress of a hydrolysis reaction of the silane coupling agent, and there is a tendency for the adhesiveness between the substrate and the cured film to increase.

In a case where the photosensitive resin composition according to the present embodiment contains water, an amount thereof with respect to 100 parts by mass of the total solid content (non-volatile components) of the photosensitive resin composition is preferably 0.1 to 5 parts by mass, more preferably 0.2 to 3 parts by mass, and still more preferably 0.5 to 2 parts by mass.

The water content of the photosensitive resin composition can be determined by a Karl Fischer method.

### (Solvent and Properties of Composition)

The photosensitive resin composition according to the present embodiment preferably contains a solvent. Accordingly, the photosensitive resin film can be easily formed on the substrate (particularly, a substrate having a step) by a coating method.

The solvent usually includes an organic solvent.

The solvent is not particularly limited as long as it can dissolve each of the above-described components and does not substantially chemically react with each of the constituent components.

Examples of the solvent include N-methyl-2-pyrrolidone, γ-butyrolactone, N,N-dimethylacetamide, dimethyl sulfoxide, diethylene glycol dimethyl ether, diethylene glycol diethyl ether, diethylene glycol dibutyl ether, propylene glycol monomethyl ether, dipropylene glycol monomethyl ether, propylene glycol monomethyl ether acetate, methyl lactate, ethyl lactate, butyl lactate, methyl-1,3-butylene glycol acetate, 1,3-butylene glycol-3-monomethyl ether, methyl pyruvate, ethyl pyruvate, and methyl-3-methoxypropionate. The solvent may be used alone or in combination of two or more thereof.

In a case where the photosensitive resin composition according to the present embodiment contains a solvent, the photosensitive resin composition according to the present embodiment is usually in a form of a varnish. More specifically, it is preferable that the photosensitive resin composition according to the present embodiment is a varnish-like composition in which at least the polyamide resin and/or the polyimide resin is dissolved in the solvent.

In a case where the photosensitive resin composition according to the present embodiment is in the form of a varnish, it is possible to perform uniform film formation by coating. In addition, in a case where the polyamide resin and/or the polyimide resin is “dissolved” in the solvent, a uniform cured film can be obtained.

In a case of using the solvent, the solvent is used so that a concentration of the total solid content (non-volatile components) in the photosensitive resin composition is preferably 10% to 50% by mass and more preferably 20% to 45% by mass. In a case where the concentration is within the range, each component can be sufficiently dissolved or dispersed. In addition, favorable coating properties can be ensured, which leads to improvement of flatness during spin coating. Furthermore, a viscosity of the photosensitive resin composition can be appropriately controlled by adjusting the content of the non-volatile components.

From another viewpoint, a proportion of the polyamide resin and/or the polyimide resin and the polyfunctional (meth)acrylate compound in the entire composition is preferably 20% to 50% by mass. By using a certain large amount of the polyamide resin and/or the polyimide resin and the polyfunctional (meth)acrylate compound, a film having an appropriate thickness is easily formed.

### (Other Components)

The photosensitive resin composition according to the present embodiment may contain a component other than the above-described components as necessary, in addition to the above-described components. Examples of such a component include an antioxidant, a filler such as silica, a sensitizing agent, and a film forming agent.

### (Regarding Various Physical Properties)

With regard to the photosensitive resin composition according to the present embodiment, further improvement in performance can be achieved by satisfying other physical properties in addition to designing the composition such that the E′₂₂₀ is 0.5 to 3.0 GPa.

From one viewpoint, in a case where the behavior of thermal expansion of a cured product of the photosensitive resin composition according to the present embodiment is appropriate, the reliability of the electronic device can be further enhanced.

Specifically,
A glass transition temperature of a cured film which is obtained by heating the photosensitive resin composition at 170° C. for 2 hours is denoted as Tg [° C.];
a coefficient of thermal expansion of the cured film in a temperature region from Tg−50[° C.] to Tg−20[° C.] is denoted as CTE1; and
a coefficient of thermal expansion of the cured film in a temperature region from Tg+20[° C.] to Tg+50[° C.] is denoted as CTE2, a value of CTE2/CTE1 is preferably 1 to 10, more preferably 1 to 7, and still more preferably 1 to 5.

By designing the photosensitive resin composition such that CTE2 is not excessively large compared to CTE1, it is considered that modification or softening of the cured film due to heating in the manufacturing process of the electronic device is further suppressed. It is considered that the reliability of the electronic device is further improved.

The value of CTE2/CTE1 is ideally preferably close to 1, but from the viewpoint of practical composition design, the lower limit thereof is, for example, approximately 1.1.

Incidentally, the value of CTE1 itself is preferably 2×10⁻⁵ to 8×10⁻⁵/° C., more preferably 2×10⁻⁵ to 8×10⁻⁵/° C., still more preferably 3×10⁻⁵ to 7×10⁻⁵/° C., and particularly preferably 4×10⁻⁵ to 6×10⁻⁵/° C.

In addition, the value of CTE2 itself is preferably 2×10⁻⁵ to 100×10⁻⁵/° C., more preferably 2×10⁻⁵ to 80×10⁻⁵/° C., still more preferably 5×10⁻⁵ to 60×10⁻⁵/° C., and particularly preferably 5×10⁻⁵ to 50×10⁻⁵/° C.

In addition, the glass transition temperature Tg is preferably 170° C. to 270° C., more preferably 170° C. to 250° C., still more preferably 200° C. to 250° C., and particularly preferably 210° C. to 230° C.

From the viewpoint other than the behavior of thermal expansion of the cured product, by designing the storage elastic modulus of the cured film of the photosensitive resin composition at 250° C. to 280° C. to an appropriate value, further improvement in performance can be achieved. The details thereof are as follows.

In the dynamic viscoelasticity measurement under [Conditions] described above, a storage elastic modulus E′₂₅₀ of the cured film of the photosensitive resin composition according to the present embodiment at 250° C. is preferably 0.3 GPa or more, more preferably 0.3 GPa or more and 3.0 GPa or less, and still more preferably 0.5 GPa or more and 2.0 GPa or less.

In the dynamic viscoelasticity measurement under [Conditions] described above, a storage elastic modulus E′₂₈₀ of the cured film of the photosensitive resin composition according to the present embodiment at 280° C. is preferably 0.1 GPa or more, more preferably 0.1 GPa or more and 2.0 GPa or less, and still more preferably 0.2 GPa or more and 1.0 GPa or less.

By designing the photosensitive resin composition so that the E′₂₅₀ or the E′₂₈₀ is within the above-described numerical range, for example, it is considered that peeling of the cured film is suppressed even in a reflow step which requires high temperature, and the reliability of the electronic device is further improved.

### <Manufacturing Method of Electronic Device and Electronic Device>

The manufacturing method of an electronic device according to the present embodiment includes:
a film forming step of forming a photosensitive resin film over a substrate using the above-described photosensitive resin composition;
an exposure step of exposing the photosensitive resin film; and
a development step of developing the exposed photosensitive resin film.

In addition, the manufacturing method of an electronic device according to the present embodiment preferably includes a thermosetting step of heating and curing the exposed photosensitive resin film, after the above-described development step. As a result, it is possible to obtain a cured film having sufficient heat resistance.

As described above, it is possible to manufacture an electronic device including the cured film of the photosensitive resin composition according to the present embodiment.

The film forming step is usually performed by applying the photosensitive resin composition onto a substrate. The film forming step can be performed using a spin coater, a bar coater, a spray device, an inkjet device, or the like.

Before the subsequent exposure step, it is preferable to perform appropriate heating for the purpose of drying the solvent in the applied photosensitive resin composition. The heating is carried out, for example, by heating at a temperature of 80° C. to 150° C. for 1 to 60 minutes.

A thickness of the photosensitive resin film after the drying varies as appropriate depending on a structure of the electronic device which is finally obtained, and for example, it is approximately 1 to 100 μm, specifically approximately 1 to 50 μm.

An exposure amount in the exposure step is not particularly limited. It is preferably 100 to 2,000 mJ/cm² and more preferably 200 to 1,000 mJ/cm².

A light source used for the exposure is not particularly limited, and any light source which emits light having a wavelength at which the photosensitizing agent in the photosensitive resin composition reacts (for example, g-rays and i-rays) may be used. Typically, a high-pressure mercury lamp is used.

As necessary, post-exposure baking may be carried out. A temperature of the post-exposure baking is not particularly limited. It is preferably 50° C. to 150° C., more preferably 50° C. to 130° C., still more preferably 55° C. to 120° C., and particularly preferably 60° C. to 110° C. In addition, a time of the post-exposure baking is preferably 1 to 30 minutes, more preferably 1 to 20 minutes, and still more preferably 1 to 15 minutes.

In the exposure step, a photomask can be used. As a result, a desired “pattern” can be formed using the photosensitive resin composition.

Examples of a developer include an organic developer and a water-soluble developer. In the present embodiment, the developer preferably contains an organic solvent. More specifically, the developer is preferably a developer containing an organic solvent as a main component (a developer in which 95% by mass or more of components is an organic solvent). By carrying out the development with the developer containing an organic solvent, it is possible to suppress swelling of the pattern due to the developer, compared to a case where the development is carrying out with an alkaline (aqueous) developer. That is, it is easier to obtain a finer pattern.

Specific examples of the organic solvent which can be used in the developer include ketone-based solvents such as cyclopentanone, ester-based solvents such as propylene glycol monomethyl ether acetate (PGMEA) and butyl acetate, and ether-based solvents such as propylene glycol monomethyl ether.

As the developer, an organic solvent developer that is composed of the organic solvent and does not contain components other than impurities which are inevitably contained may be used. The impurities which are inevitably contained include a metal element and water, and from the viewpoint of preventing contamination of the electronic device, and the like, it is better to contain fewer impurities which are inevitably contained.

A method of bringing the developer into contact with the photosensitive resin layer 2510 is not particularly limited. A generally known method such as a dipping method, a paddle method, and a spraying method can be appropriately applied.

A time of the development step is appropriately adjusted based on the film thickness of the resin film, the shape of the pattern to be formed, and the like, usually in a range of appropriately 5 to 300 seconds, preferably appropriately 10 to 120 seconds.

Conditions of the thermosetting step are not particularly limited, and for example, the thermosetting step can be performed at a heating temperature of approximately 160° C. to 250° C. for approximately 30 to 240 minutes.

Hereinafter, the manufacturing method of an electronic device will be described with reference to the drawings. A specific example of the manufacturing method of an electronic device described is a method characterized by sealing a semiconductor chip 40 from a surface of the semiconductor chip 40 opposite to a side on which electrode pads 30 are arranged, so-called manufacturing method of a fan-out wafer level package (FO-WLP) type electronic device.

First, as shown in FIG. 1(a), a structural body in which a plurality of semiconductor chips 40 obtained by cutting a semiconductor wafer, which has been passivated in advance by forming a passivation film 50, into pieces are arranged at predetermined intervals and a terminal surface of the semiconductor chip 40 (a surface on which an electrode pad 30 is disposed) is attached to an adhesive surface of an adhesive member 200 is prepared. As a material for forming the passivation film 50, a photosensitive resin composition used for forming a first insulating resin film 60 described later can be used.

In the structural body of FIG. 1(a), it is preferable that the plurality of semiconductor chips 40 are embedded inside a sealing material 10 such that the electrode pads 30 provided on each surface of the plurality of semiconductor chips 40 all face in the same direction.

A pillar-shaped conductor portion made of a metal such as copper may be formed on the electrode pad 30 included in the semiconductor chip 40. Furthermore, a solder bump may be formed on an end surface of the conductor portion opposite to a side on which the electrode pad is disposed.

Next, as shown in FIG. 1(b), the plurality of semiconductor chips 40 attached to the adhesive member 200 are sealed with a cured product of a resin composition for sealing a semiconductor. In the present embodiment, the cured product of the resin composition for sealing a semiconductor represents the sealing material. As the resin composition for sealing a semiconductor, known materials can be used, and examples thereof include an epoxy resin composition containing an epoxy resin, an inorganic filler, and a curing agent.

Examples of a method of sealing the semiconductor chip 40 using the resin composition for sealing a semiconductor include a transfer molding method, a compression molding method, an injection molding method, and a lamination method. Among these, from the viewpoint of forming the sealing material 10 without leaving any unfilled portions, a transfer molding method, a compression molding method, or a lamination method is preferable. Therefore, it is preferable that the resin composition for sealing a semiconductor, which is used in the present manufacturing method, has a granular shape, a powdery granular shape, a tablet shape, or a sheet-like form. In addition, from the viewpoint of suppressing misalignment of the semiconductor chip 40 during molding of the sealing material 10, a compression molding method is particularly preferable.

Next, as shown in FIG. 1(c), the adhesive member 200 is peeled off. By doing so, the structural body in which the plurality of semiconductor chips 40 having the electrode pads 30 on the surfaces are embedded inside the sealing material 10 can be obtained. It is preferable that the adhesive member 200 is peeled off from the structural body after reducing adhesiveness between the adhesive member 200 and the structural body. Specific examples thereof include a method of reducing the adhesiveness by, for example, subjecting an adhesive part between the adhesive member 200 and the structural body to irradiation with ultraviolet rays or heat treatment to deteriorate an adhesive layer of the adhesive member 200 forming the adhesive part.

The adhesive member 200 is not particularly limited as long as it adheres to the semiconductor chip 40, and examples thereof include a member formed by laminating a back-grinding tape and an adhesive layer.

The structural body shown in FIG. 1(c) is a structural body in which the surface of the semiconductor chip 40 opposite to the side on which the electrode pad 30 is disposed is sealed with the sealing material 10, but in the present manufacturing method, a step of, before peeling off the adhesive member 200, polishing and removing the sealing material 10 by a known method so that the surface of the semiconductor chip 40 opposite to the side on which the electrode pad 30 is disposed is exposed.

Next, as shown in FIG. 2(a), a first insulating resin film 60 is formed on the surface of the obtained structural body on a side in which the electrode pad 30 is embedded. Specifically, the first insulating resin film 60 is formed by applying a varnish-like resin composition onto the surface of the above-described structural body on a side in which the electrode pad 30 is embedded, and drying the resin composition. A film thickness of the first insulating resin film 60 can be, for example, 1 to 300 μm. As a method of applying the resin composition, a known method such as a spin coating method, a slit coating method, and an inkjet method can be adopted. Among these, it is preferable to adopt a spin coating method.

In the present manufacturing method, as a resin material constituting the first insulating resin film 60, it is preferable to use the above-described photosensitive resin composition (composition described in the section of <Photosensitive resin composition>).

In the present manufacturing method, it is preferable that, before forming the first insulating resin film 60, the surface of the sealing material 10 on a side in which the first insulating resin film 60 is formed is plasma-treated. By doing so, wettability of the first insulating resin film 60 can be improved. As a result, adhesiveness between the sealing material 10 and the first insulating resin film 60 can be further improved.

In the plasma treatment, for example, argon gas, an oxidizing gas, or a fluorine-based gas can be used as a treatment gas. Examples of the oxidizing gas include O₂ gas, O₃ gas, CO gas, CO₂ gas, NO gas, and NO₂ gas. As the treatment gas, for example, it is preferable to use an oxidizing gas. In addition, as the oxidizing gas, for example, it is preferable to use O₂ gas. As a result, it is possible to form a specific functional group on the surface of the sealing material 10. Therefore, the adhesiveness and coating properties of the first insulating resin film 60 with the sealing material 10 can be further improved, and the reliability of the electronic device can be further improved.

Conditions of the plasma treatment are not particularly limited, and the plasma treatment may be an ashing treatment or a treatment of contacting with plasma derived from an inert gas. In addition, the plasma treatment according to the present manufacturing method is preferably a plasma treatment carried out without applying a bias voltage to the treatment target or a plasma treatment carried out using a non-reactive gas.

In addition, in the present manufacturing method, a chemical liquid treatment may be carried out instead of the plasma treatment, or both the plasma treatment and the chemical liquid treatment may be carried out. Examples of an agent which can be used for the chemical liquid treatment include alkaline permanganate aqueous solution such as potassium permanganate and sodium permanganate.

Next, as shown in FIG. 2(b), a first opening portion 250 in which a part of the electrode pad 30 is exposed is formed in the first insulating resin film 60. As a method of forming the first opening portion 250, an exposure development method or a laser processing method can be used. In addition, it is preferable to subjecting the formed first opening portion 250 to a descum treatment in which a scum (resin residue) generated in a case of forming the first opening portion 250 is removed.

The descum treatment may be carried out by plasma irradiation. In this case, as a treatment gas, for example, argon gas, O₂ gas, O₃ gas, CO gas, CO₂ gas, NO gas, NO₂ gas, or a fluorine-based gas can be used.

Next, as shown in FIG. 2(c), a conductive film 110 is formed to cover the exposed electrode pad 30 and the first insulating resin film 60. As the conductive film 110, for example, any one of an electrolytic copper plating film, a solder plating film, a tin plating film, a two-layer plating film having a gold plating film laminated on a nickel plating film, or an under bump metal (UBM) film formed by electroless plating can be used. In addition, a film thickness of the conductive film 110 can be, for example, 2 to 10 μm.

From the viewpoint of improving durability of an electronic device 100 finally obtained, a surface of the obtained conductive film 110 may be subjected to a plasma treatment by the same method as described above.

As the plating treatment method, for example, an electrolytic plating method or an electroless plating method can be adopted. In a case where the electroless plating method is used, the conductive film 110 can be formed as follows. Hereinafter, an example of forming the conductive film 110 made of two layers of nickel and gold will be described, but the present invention is not limited thereto.

First, a nickel plating film is formed. In a case where the electroless plating is carried out, the structural body shown in FIG. 2(b) is immersed in a plating liquid. In this manner, it is possible to form the conductive film 110 on the electrode pad 30 and the surface of the first insulating resin film 60. As the plating liquid, a plating liquid containing nickel lead and a reducing agent, for example, hypophosphite can be used. Next, electroless gold plating is carried out on the nickel plating 25 film. The method of electroless gold plating is not particularly limited, and for example, substitution gold plating by substituting gold ions for base metal ions can be carried out.

In this way, in FO-WLP, the semiconductor chip 40 is embedded in the sealing material 10. A circuit surface of the semiconductor chip 40 is exposed to the outside, and a boundary between the semiconductor chip 40 and the sealing material 10 is formed. The conductive film 110 (rewired layer) connected to the electrode pad 30 of the semiconductor chip 40 is also provided in a region of the sealing material 10, in which the semiconductor chip 40 is embedded, and a bump is electrically connected to the electrode pad 30 of the semiconductor chip 40 through the conductive film 110 (rewired layer). A pitch of the bump can be set to be large with respect to a pitch of the electrode pad 30 of the semiconductor chip 40.

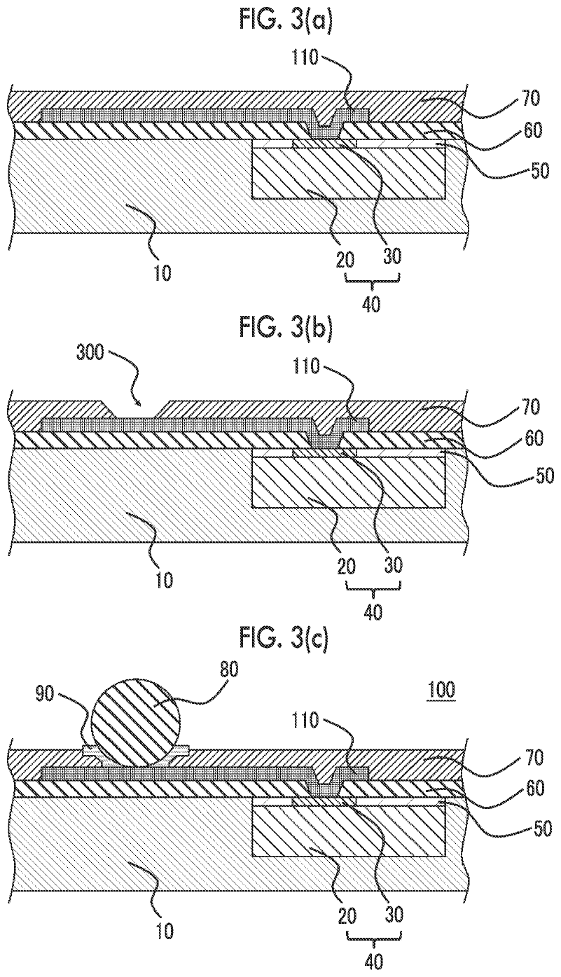

Next, as shown in FIG. 3(a), a second insulating resin film 70 is formed on the surface of the conductive film 110. Thereafter, in the present embodiment, as shown in FIG. 3(b), a second opening portion 300 in which a part of the conductive film 110 is exposed is formed.

As a method of forming the second insulating resin film 70 and a method of forming the second opening portion 300, the same method as the method of forming the first insulating resin film 60 and the method of forming the first opening portion 250 described can be used. In addition, as a material for forming the second insulating resin film 70, the photosensitive resin composition used for forming the first insulating resin film 60 (that is, the composition described in the section of <Photosensitive resin composition>) can be used.

Next, as shown in FIG. 3(c), a solder bump 80 or an end of a bonding wire is melted and fused on the conductive film 110 exposed in the second opening portion 300. In this manner, it is possible to obtain the electronic device 100 according to the present embodiment.

Thereafter, although not shown, by cutting the electronic device 100 along a dicing line formed in the electronic device 100 to include at least one semiconductor chip 40, the electronic device 100 can be cut into pieces of a plurality of semiconductor packages (electronic devices).

In addition, in the present manufacturing method, an electronic device having a multilayer wiring structure in which a plurality of conductive films (wire layers) and insulating resin films are laminated in this order, starting from the structural body shown in FIG. 3(b), can also be manufactured. According to the present manufacturing method, for example, it is possible to manufacture an electronic device including a four-layer conductive film (wiring layer) and a five-layer insulating resin film. In this case, as a method of forming the conductive film (wiring layer), the same method as the method of forming the conductive film 110 can be used. In addition, as a method of forming the insulating resin film, the same method as the method of forming the first insulating resin film 60 can be used.

Even in a case where the electronic device having the above-described multilayer wiring structure is manufactured, by the same method as described above, the solder bump 80 or the end of the bonding wire is melted on the outermost layer and fused to the conductive film (wiring layer), so that it is possible to electrically connect the obtained electronic device.

The present manufacturing method relates to a method of starting from the structural body shown in FIG. 1(c) and forming the insulating resin film and the conductive film (wiring layer) only on one surface of the structural body, but in a case where the structural body shown in FIG. 1(c) is in a state in which the surface of the semiconductor chip 40 opposite to a side on which the electrode pad 30 is disposed is also exposed, the insulating resin film may be formed on both surfaces of the structural body.

The present manufacturing method can also be applied to a process for manufacturing a chip-sized semiconductor package, but from the viewpoint of improving productivity of the semiconductor package, the present manufacturing method may be applied to a process for manufacturing a so-called wafer level package or a process for manufacturing a panel level package based on the premise of using a large-area panel larger than the wafer size.

The embodiments of the present invention have been described above, but these are examples of the present invention and various configurations other than the above can be adopted.

In addition, the present invention is not limited to the above-described embodiments, and modifications, improvements, and the like within the range in which the object of the present invention can be achieved are included in the present invention.

### EXAMPLES

Embodiments of the present invention will be described in detail based on Examples and Comparative Example. As a reminder, the present invention is not limited to Examples.

In the following, “DMAc” is an abbreviation for dimethylacetamide. Other abbreviations will be appropriately described in the description.

### <Synthesis of Polymer>

### (Synthesis of Polymer (A-1))

64.1 g (0.20 mol) of 2,2′-bis(trifluoromethyl)-4,4′-diaminobiphenyl <TFMB>, 97.7 g (0.22 mol) of 4,4′-(hexafluoroisopropylidene)diphthalic acid dianhydride <6FDA>, and 500 g of DMAc were charged into a 3 L glass separable flask equipped with a stirring device and a stirring blade, and stirred to dissolve TFMB and 6FDA in DMAc. The mixture was further stirred at room temperature for 12 hours under a nitrogen stream to carry out a polymerization reaction, thereby obtaining a polyamide acid solution.

16 g of pyridine was added to the obtained polyamide acid solution. Next, 82 g of acetic acid anhydride was added dropwise thereto at room temperature. Thereafter, the liquid temperature was kept at 20° C. to 100° C., and stirring was continued for 24 hours to carry out an imidization reaction. In this manner, a polyimide solution was obtained.

The obtained polyimide solution was put into 1,000 g of methanol while stirring in a container with a volume of 5 L to precipitate a polyimide resin. Thereafter, the solid polyimide resin was filtered and separated using a suction filtration device, and further washed using 1,000 g of methanol. Using a vacuum dryer, drying was carried out at 100° C. for 24 hours, and further drying was carried out at 200° C. for 3 hours. As a result, a polymer (A-1) which was a polyimide powder having an acid anhydride group at a terminal was obtained.

A weight-average molecular weight (Mw) of the polymer (A-1), measured by GPC, was 25,000.

In addition, ¹H-NMR of the polymer (A-1) was measured, and an imidization ratio (as defined above) was calculated from the quantitative value of the amide peak with respect to the peak of the aromatic ring of the polyimide. The imidization ratio was 99% or more.

### (Synthesis of Polymer (A-2))

A polymer was synthesized in the same manner as the polymer (A-1), except that 56.4 g (0.176 mol) of TFMB and 12.4 g (0.024 mol) of 2,2,-bis[4-(4-aminophenoxy)phenyl]-1,1,1,3,3,3-hexafluoropropane <BAPP-F> were used instead of 64.1 g (0.20 mol) of TFMB. A polymer (A-2) which was a polyimide powder having an acid anhydride group at a terminal was obtained.

A weight-average molecular weight (Mw) of the polymer (A-2), measured by GPC, was 26,000. In addition, the imidization ratio of the polymer (A-2), measured by NMR, was 993 or more.

### (Synthesis of Polymer (A-3))

A polymer was synthesized in the same manner as the polymer (A-1), except that 78.2 g (0.176 mol) of 6FDA and 13.7 g (0.044 mol) of 4,4′-oxydiphthalic acid dianhydride <ODPA> were used instead of 97.7 g (0.22 mol) of 6FDA. A polymer (A-3) which was a polyimide powder having an acid anhydride group at a terminal was obtained.

A weight-average molecular weight (Mw) of the polymer (A-3), measured by GPC, was 24,000. In addition, the imidization ratio of the polymer (A-3), measured by NMR, was 99% or more.

### (Synthesis of Polymer (A-4))

A polymer was synthesized in the same manner as the polymer (A-1), except that 83.1 g (0.187 mol) of 6FDA and 9.71 g (0.033 mol) of 3,3′, 4,4′-biphenyltetracarboxylic acid dianhydride <BPDA> were used instead of 97.7 g (0.22 mol) of 6FDA. A polyimide resin (A-4) having an acid anhydride group at a terminal was obtained.

A weight-average molecular weight (Mw) of the polymer (A-4), measured by GPC, was 24,000. In addition, the imidization ratio of the polymer (A-4), measured by NMR, was 99, or more.

### (Synthesis of Polymer (A-5))

A polymer was synthesized in the same manner as the polymer (A-1), except that 85.7 g (0.20 mol) of 1,4,-bis(4-amino-2-trifluoromethylphenoxy)benzene was used instead of 64.1 g (0.20 mol) of TFMB. A polymer (A-5) which was a polyimide powder having an acid anhydride group at a terminal was obtained.

A weight-average molecular weight (Mw) of the polymer (A-5), measured by GPC, was 25,000. In addition, the imidization ratio of the polymer (A-5), measured by NMR, was 99′% or more.

### <Preparation of Photosensitive Resin Composition>

Each of raw materials blended according to Table 1 shown later was stirred at room temperature until the raw materials were completely dissolved to obtain a solution. Thereafter, the solution was filtered through a nylon filter having a pore size of 0.2 μm. In this manner, a varnish-like photosensitive resin composition was obtained.

Details of the raw materials of each component in Table 1 are as follows.

<Polyamide Resin and/or Polyimide Resin>
(A-1) Polymer synthesized above
(A-2) Polymer synthesized above
(A-3) Polymer synthesized above
(A-4) Polymer synthesized above
(A-5) Polymer synthesized above

Structures of each of the above-described polymers are shown below.

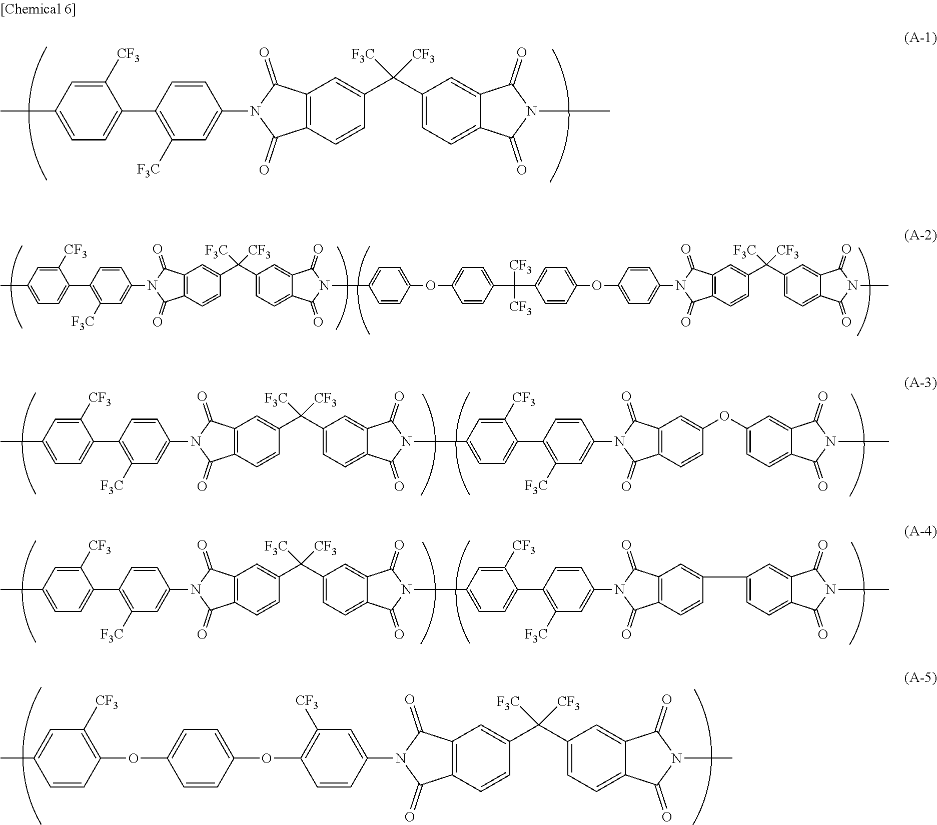

### <Polyfunctional (Meth)Acrylate Compound>

(B-1) VISCOAT #802 (manufactured by OSAKA ORGANIC CHEMICAL INDUSTRY LTD., mixture of compounds having 5 to 10 acryloyl groups per molecule)
(B-2) NK ESTER A-9550 (manufactured by SHIN-NAKAMURA CHEMICAL CO, LTD., mixture of compounds having 5 or 6 acryloyl groups per molecule)
(B-3) VISCOAT #300 (manufactured by OSAKA ORGANIC CHEMICAL INDUSTRY LTD., mixture of compounds having 3 or 4 acryloyl groups per molecule)
(B-4) VISCOAT #230 (manufactured by OSAKA ORGANIC CHEMICAL INDUSTRY LTD., compound having 2 acryloyl groups per molecule)

Structures of (B-1) to (B-4) above are shown below.

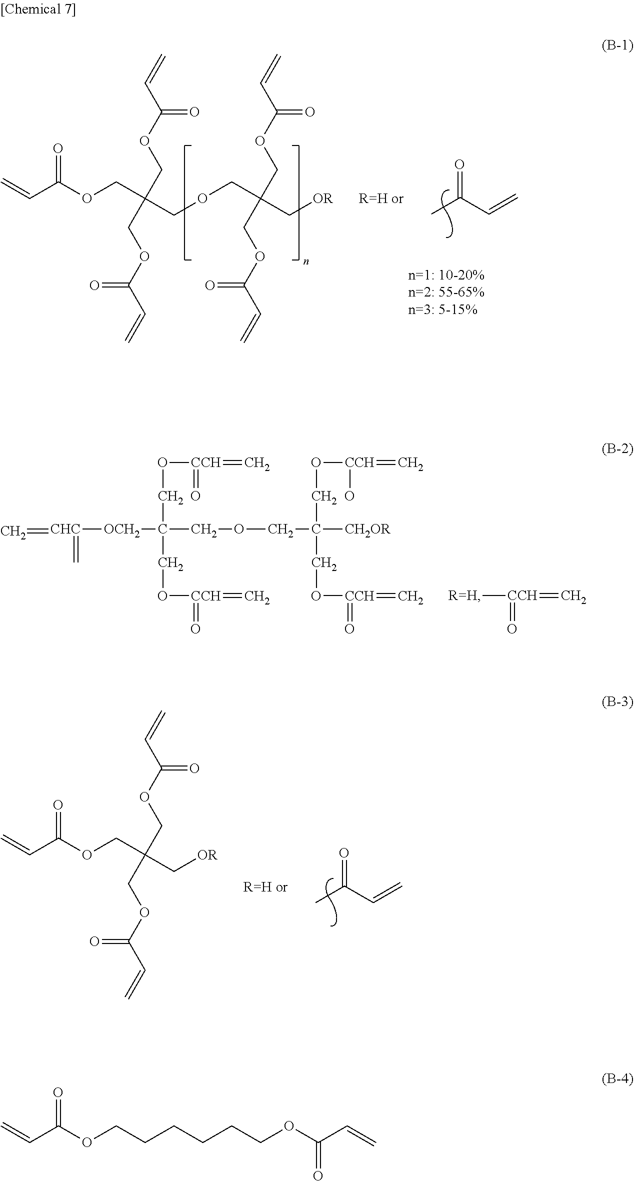

### <Photosensitizing Agent>

(C-1) Irgacure OXE01 (manufactured by BASF, oxime ester type photoradical generator)
(C-2) ADEKA ARKLS NCI-730 (manufactured by ADEKA CORPORATION, oxime ester type photoradical generator)

### <Thermal Radical Generator>

(D-1) PERKADOX BC (manufactured by Kayaku Akzo Corporation, organic peroxide, dicumyl peroxide)

### <Epoxy Resin>

(E-1) TECHMORE VG3101L (manufactured by Printec Co.)
(E-2) CELLOXIDE 2021P (manufactured by Daicel Corporation)

### <Curing Catalyst>

(F-1) tetraphenylphosphonium 4,4′-sulfonyl diphenolate

A method of synthesizing the curing catalyst (F-1) is as follows.

37.5 g (0.15 mol) of 4,4′-bisphenol S and 100 ml of methanol were charged into a separable flask equipped with a stirring device and dissolved under stirring at room temperature to prepare a solution 1. A solution obtained by dissolving 4.0 g (0.1 mol) of sodium hydroxide in 50 ml of methanol in advance was added to the solution 1 under stirring to prepare a solution 2. Subsequently, a solution obtained by dissolving 41.9 g (0.1 mol) of tetraphenylphosphonium bromide in 150 ml of methanol in advance was added to the solution 2 to prepare a solution 3. Stirring of the solution 3 was continued for a while, and 300 mL of methanol was added to the solution 3 to prepare a solution 4. Thereafter, the solution 4 in the flask was added dropwise to a large amount of water under stirring to obtain white precipitates. The precipitates were filtered and dried. In this manner, a target product of white crystal was obtained.

### <Silane Coupling Agent>

(G-1) KBM-503 (manufactured by Shin-Etsu Chemical Co., Ltd., (meth)acryloyl group-containing silane coupling agent)
(G-2) X-12-967C (manufactured by Shin-Etsu Chemical Co., Ltd., silane coupling agent with a cyclic anhydride structure)

### <Surfactant>

(H-1) FC4432 (manufactured by 3M Co., Ltd., fluorine-based)

### <Solvent>

(J-1) ethyl lactate (EL)
(J-2) γ-butyrolactone (GBL)

### <Dynamic Viscoelasticity Measurement of Cured Film (Measurement of E′₂₂₀ and the Like)>

### (Production of Test Piece)

An 8-inch silicon wafer was spin-coated with the photosensitive resin composition such that a film thickness after drying was 10 μm, and heated at 120° C. for 3 minutes to obtain a coating film.

The obtained coating film was exposed with a high-pressure mercury lamp at 1,000 mJ/cm². Thereafter, post-exposure baking was carried out at 120° C. for 3 minutes, and then the product was immersed in cyclopentanone for 30 seconds. Thereafter, under a nitrogen atmosphere, heating was carried out at 170° C. for 2 hours to carry out a curing treatment. As a result, a cured film of the photosensitive resin composition was obtained.

The obtained cured product was cut into individual pieces together with the silicon wafer to a width of 5 mm. Each piece was immersed in a 2% by mass hydrofluoric acid aqueous solution to peel off the cured film from the wafer.

The peeled cured film was dried at 60° C. for 10 hours to obtain a test piece (30 mm×5 mm×10 μm thickness).

Using a dynamic viscoelasticity measurement device (manufactured by TA Instruments, Q800), the obtained test piece was heated from 30° C. to 300° C. under conditions of nitrogen atmosphere, frequency of 1 Hz, tensile mode, and heating rate of 5° C./min, and a storage elastic modulus with respect to temperature was measured. From the obtained storage elastic modulus (E′) curve, the storage elastic modulus [MPa] at 220° C., 250° C., and 280° C. was read.

### <Measurement of Coefficient of Thermal Expansion and Glass Transition Temperature (Tg)>

Using a thermomechanical analysis device (manufactured by Seiko Instruments Inc., TMA/SS6000), a test piece obtained by the same manner as in the dynamic viscoelasticity measurement of the cured film described above was heated to 300° C. at a heating rate of 10° C./min. A relationship between the temperature and the amount of displacement in this case was graphed.

A glass transition temperature (Tg) of the cured product was obtained from the position of the inflection point in the obtained graph. In addition, in the obtained graph, a coefficient of linear expansion in a region of Tg−50 [° C.] to Tg−20 [° C.] was obtained as CTE1, and a coefficient of linear expansion in a region of Tg+20[° C.] to Tg+50[° C.] was obtained as CTE2. The value of CTE2/CTE1 was calculated.

### <Reliability Evaluation (Temperature Cycle Test)>

### (Production of Substrate for Reliability Evaluation)

A 12-inch silicon wafer was spin-coated with the photosensitive resin composition such that a film thickness after drying was 5 μm, and heated at 120° C. for 3 minutes to obtain a coating film.

The obtained coating film was exposed with a high-pressure mercury lamp at 1,000 mJ/cm². Thereafter, post-exposure baking was carried out at 120° C. for 3 minutes, and then the product was immersed in cyclopentanone for 30 seconds. Thereafter, under a nitrogen atmosphere, heating was carried out at 170° C. for 2 hours to carry out a curing treatment. As a result, a cured film of a first layer of the photosensitive resin composition was obtained.

Ti and Cu were each deposited on the obtained cured film at thicknesses of 500 Å and 3000 Å by a sputtering treatment. Thereafter, Cu wiring was produced to have a height of 5 μm by an electrolytic plating method through a resist. After peeling off the resist layer, the spattering Cu and the sputtering Ti were etched to produce a Cu wiring of line/space=2 μm/2 μm.

Subsequently, the photosensitive resin composition was treated in the same manner as in the first layer, except that the film thickness was changed to 10 μm, thereby obtaining a substrate for reliability evaluation.

### (Reliability Test)

The substrate for reliability evaluation, which had been obtained as described above, was set in a temperature cycle test device (TCT device), and a treatment was carried out for 1000 cycles with one cycle of raising the temperature from −60° C. to 200° C. and then lowering the temperature to −60° C.

Subsequently, a cross section of the Cu wiring portion was exposed by a focused ion beam (FIB) treatment, and observed by SEM. In each of Examples and Comparative Example, a total of 10 locations of an interface between the wiring and the resin film were observed.

A case where peeling was not observed at all 10 locations was evaluated as ⊚ (very good), a case where peeling was observed at one or two of the 10 locations was evaluated as o (good), and a case where peeling was observed at three or more locations was evaluated as x (poor).

### <Evaluation of Insulation Reliability>

### (Production of Sample for Insulation Reliability)

A Cu wiring board was produced in which interdigitated Cu wiring having a width of 5 μm/a pitch of 5 μm, and a height of 5 μm was formed on a silicon wafer with an oxide film.

The photosensitive resin composition was applied onto the above-described Cu wiring board by spin coating such that a film thickness after drying (thickness in a portion without wiring) was 10 μm, and dried at 120° C. for 3 minutes to form a photosensitive resin film.

The obtained photosensitive resin film was exposed at 300 mJ/cm² using a high-pressure mercury lamp. Thereafter, the photosensitive resin film was immersed in cyclopentanone for 30 seconds. Thereafter, the photosensitive resin film was heat-treated at 170° C. for 2 hours under a nitrogen atmosphere to obtain a cured film. The cured film was used as a sample for evaluation of insulation reliability.

### (Evaluation of Insulation Reliability)

A simulated electronic device for evaluation, in which an end (Cu electrode) of the Cu wiring of the substrate produced in (Production of sample for insulation reliability) described above and an electrode wiring were connected by soldering, was produced. The electronic device was placed in an environment of 130° C./85% RH while applying a bias of 3.5 V with a B-HAST device.

An insulation resistance value between the Cu wirings of the Cu wiring board was automatically measured at an interval of 6 minutes, and a case where the insulation resistance value was 1.0×10⁴Ω or less was regarded as an insulation breakdown. A time from the start of the test to the insulation breakdown was measured. In the table later, a case where the time was 210 hours or more was described as ⊚ (very good), a case where the time was from 50 hours to 210 hours was described as ∘ (good), and a case where the time was less than 50 hours was described as x (poor).

### <Evaluation of Shear Strength at 250° C.>

In the same manner as in <Evaluation of patterning properties>, a residual pattern of 100 μm×100 μm was produced on an 8-inch silicon wafer on which a copper plating film had been formed. Thereafter, a curing treatment was carried out at 170° C. for 2 hours under a nitrogen atmosphere to obtain a sample for shear strength measurement.

Using a die shear device (manufactured by Nordson Advanced Technology K.K., Dage-4000), a shear strength (heated shear strength, unit: MPa) of the obtained sample at 250° C. was measured under conditions of a shear rate of 200 nm/sec and a shear height of 1 Um. As the value is larger, the cured film is less likely to be peeled off even in a case of being exposed to high temperature. That is, from the viewpoint of reliability of the electronic device, it is preferable that the value is larger.

### <Evaluation of Curing Shrinkage Rate>

An 8-inch silicon wafer was spin-coated with the photosensitive resin composition such that a film thickness after drying was 10 μm. Subsequently, heating was carried out at 120° C. for 3 minutes to obtain a photosensitive resin film.

The obtained photosensitive resin film was exposed with a high-pressure mercury lamp at 300 mJ/cm². Thereafter, the photosensitive resin film was immersed in cyclopentanone for 30 seconds, and dried with a spin dry to obtain a developed film of the photosensitive resin composition. A film thickness of the developed film was measured, and denoted as a film thickness A.

Thereafter, the developed film was cured by a heat treatment at 170° C. for 2 hours under a nitrogen atmosphere. As a result, a cured film of the photosensitive resin composition was obtained. A film thickness of the cured film was measured, and denoted as a film thickness B.

The film thickness A and the film thickness B were substituted into the following expression, and a curing shrinkage rate was calculated. It is preferable that the curing shrinkage rate is small in order to maintain flatness on a wiring after coating.

Curing shrinkage rate [%]={(Film thickness A−Film thickness B)/Film thickness A}×100

### <Evaluation of Flatness During Coating (Step Embedding Flatness)>

A Cu wiring board was produced in which Cu wiring having a width of 5 μm/a pitch of 5 μm, and a height of 5 μm was formed on a silicon wafer with an oxide film. The photosensitive resin composition was applied onto the Cu wiring board by spin coating such that a film thickness after drying was 10 μm, and dried at 120° C. for 3 minutes to form a photosensitive resin film.

The obtained photosensitive resin film was exposed with a high-pressure mercury lamp at 300 mJ/cm². Thereafter, the photosensitive resin film was immersed in cyclopentanone for 30 seconds. Thereafter, a heat treatment was carried out at 170° C. for 2 hours under a nitrogen atmosphere to form a cured film on the substrate.

The obtained substrate with a cured film was divided, a cross section thereof was polished. A surface unevenness of the photosensitive resin film was evaluated by SEM observation of the cross section. A sample having a surface unevenness of 1 μm or less was evaluated as ∘ (good), a sample having a surface unevenness of 1 to 3 μm was evaluated as Δ (usable level), and a sample having a surface unevenness of more than 3 μm was evaluated as x (poor).

### <Evaluation of Tensile Elongation Rate>

First, a test piece was produced in the same manner as in (Production of test piece) of <Dynamic viscoelasticity measurement of cured film (measurement of E′₂₂₀ and the like)> described above.

Using a tensile tester (manufactured by ORIENTEC CO., LTD., TENSILON RTC-1210A), the obtained test piece was subjected to a tensile test in an atmosphere of 23° C. in accordance with JIS K 7161, and a tensile elongation rate of the test piece was measured. A drawing speed in the tensile test was 5 mm/min.

### <Evaluation of Patterning Properties>

The photosensitive resin composition was applied onto an 8-inch silicon wafer using a spin coater such that a film thickness after drying was 5 μm. Thereafter, the photosensitive resin composition was dried on a hot plate at 120° C. for 3 minutes to obtain a photosensitive resin film (photosensitive resin film A).

Using an i-ray stepper (NSR-4425i manufactured by Nikon Corporation), the photosensitive resin film was irradiated with i-rays through a mask manufactured by TOPPAN Printing Co., Ltd. (test chart No. 1; a residual pattern having a width of 0.5 to 50 μm and a cutout pattern were drawn) while changing an exposure amount.

Thereafter, development was carried out for 30 seconds with cyclopentanone as a developer, and the sample was spin-dried at 2500 rotation for 10 seconds to obtain a developed film (negative pattern).

A sample in which a via hole of 7 μmΦ was opened was evaluated as ⊚ (very good), a sample in which a via hole of 10 μmΦ was opened was evaluated as o (good), and a sample in which a via hole of 10 μm was not opened was evaluated as x (poor).

Table 1 collectively shows the blending of the raw materials of each composition, and measurement and evaluation results of each composition.

TABLE 1

| | | | | | | | | | | | | | | | | | Compar- |
|---|---|---|---|---|---|---|---|---|---|---|---|---|---|---|---|---|---|
| | | | | | | | | | | | | | | | | | ative |
| | | | Exam- | Exam- | Exam- | Exam- | Exam- | Exam- | Exam- | Exam- | Exam- | Exam- | Exam- | Exam- | Exam- | Exam- | Exam- |
| | | | ple 1 | ple 2 | ple 3 | ple 4 | ple 5 | ple 6 | ple 7 | ple 8 | ple 9 | ple 10 | ple 11 | ple 12 | ple 13 | ple 14 | ple 1 |
| Formulation | Polyamide resin and/ | (A-1) | 100 | — | — | — | 100 | 100 | 100 | 100 | 100 | 100 | 100 | 100 | 100 | 100 | — |
| [part by | or polyimide resin | (A-2) | — | 100 | — | — | — | — | — | — | — | — | — | — | — | — | — |
| mass] | | (A-3) | — | — | 100 | — | — | — | — | — | — | — | — | — | — | — | — |
| | | (A-4) | — | — | — | 100 | — | — | — | — | — | — | — | — | — | — | — |
| | | (A-5) | — | — | — | — | — | — | — | — | — | — | — | — | — | — | 100 |
| | Polyfunctional | (B-1) | [symbol] | [symbol] | [symbol] | [symbol] | [symbol] | [symbol] | [symbol] | [symbol] | [symbol] | [symbol] | [symbol] | [symbol] | [symbol] | [symbol] | — |
| | (meth)acrylate | (B-2) | 20 | 20 | 20 | 20 | 20 | [symbol] | 20 | 20 | 20 | 20 | 20 | 20 | 20 | 20 | — |
| | | (B-3) | 20 | 20 | 20 | 20 | 10 | [symbol] | 20 | 20 | 20 | 20 | 20 | 20 | 20 | 20 | — |
| | | (B-4) | — | — | — | — | — | — | 20 | — | — | — | — | — | — | — | [symbol] |
| | Photosensitizing | ( [symbol] ) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| | agent:photoradical | ( [symbol] ) | [symbol] | [symbol] | [symbol] | [symbol] | [symbol] | [symbol] | [symbol] | [symbol] | [symbol] | [symbol] | [symbol] | [symbol] | [symbol] | [symbol] | — |
| | generator | | | | | | | | | | | | | | | | |
| | Thermal radical | ( [symbol] ) | 10 | 10 | 10 | 10 | 10 | 10 | 10 | 10 | [symbol] | 20 | — | 10 | 10 | 10 | — |
| | generator | | | | | | | | | | | | | | | | |
| | Epoxy resin | (B-1) | [symbol] | [symbol] | [symbol] | [symbol] | [symbol] | [symbol] | [symbol] | [symbol] | [symbol] | [symbol] | [symbol] | — | [symbol] | [symbol] | — |
| | Curing catalyst | (B-2) | [symbol] | [symbol] | [symbol] | [symbol] | [symbol] | [symbol] | [symbol] | [symbol] | [symbol] | [symbol] | [symbol] | — | [symbol] | [symbol] | — |
| | Silane coupling | ( [symbol] ) | [symbol] | [symbol] | [symbol] | [symbol] | [symbol] | [symbol] | [symbol] | [symbol] | [symbol] | [symbol] | [symbol] | [symbol] | — | [symbol] | — |
| | agent | ( [symbol] ) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| | Surfactant | ( [symbol] ) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| | Water | ( [symbol] ) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| | Organic solvent | ( [symbol] ) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| | | ( [symbol] ) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |

| | | | | | | | | | | | | | | | | |
|---|---|---|---|---|---|---|---|---|---|---|---|---|---|---|---|---|
| Storage elastic [symbol] | ( [symbol] ) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| Storage elastic [symbol] | (GPa) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| Storage elastic [symbol] | (GPa) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| Heat resistance: glass [symbol] | (GPa) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | ( [symbol] /° C.) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | ( [symbol] /° C.) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | — | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| Reliability (temperature cycle test) | — | ⊚ | ⊚ | ⊚ | ⊚ | ⊚ | ⊚ | ⊚ | ⊚ | ⊚ | ⊚ | ◯ | ◯ | ◯ | ◯ | X |
| Insulation reliability | — | ⊚ | ⊚ | ⊚ | ⊚ | ⊚ | ⊚ | ⊚ | ⊚ | ⊚ | ⊚ | ⊚ | ⊚ | ⊚ | ◯ | ◯ |
| [symbol] strength at [symbol] | (MPa) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| Curing shrinkage rate | — | ⊚ | ⊚ | ⊚ | ⊚ | ⊚ | ⊚ | ⊚ | ⊚ | ⊚ | ⊚ | ⊚ | ⊚ | ⊚ | ⊚ | X |
| Step [symbol] flatness | (%) | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| Tensile elongation rate | | | | | | | | | | | | | | | | |
| [symbol] properties | — | ⊚ | ⊚ | ⊚ | ⊚ | ⊚ | ⊚ | ⊚ | ⊚ | ⊚ | ⊚ | ⊚ | ⊚ | ⊚ | ⊚ | ⊚ |

[symbol]

indicates data missing or illegible when filed

As shown in Table 1, the results of the temperature cycle test, the evaluation results of insulation reliability, and the shear strength at 250° C. of the photosensitive resin compositions of Examples 1 to 14 (containing the polyamide resin and/or the polyimide resin, in which the E′₂₂₀ was 0.5 to 3.0 GPa) were all good. From these evaluation results, it was shown that, by curing the photosensitive resin composition according to the present embodiment by heating at approximately 170° C. to form a cured film, it was possible to manufacture an electronic device having high reliability.

In addition, the curing shrinkage rate of the cured products of the photosensitive resin compositions of Examples 1 to 14 was small, and the evaluation of step embedding flatness thereof was good. Furthermore, the cured products of the photosensitive resin compositions of Examples 1 to 14 stretched moderately. Moreover, the photosensitive resin compositions of Examples 1 to 14 had sufficient patterning performance during the manufacture of the electronic device.

In a case where Examples were studied in more detail, the following could be understood.

From the comparison between Example 11 and other Examples, by using the thermal radical generator, the glass transition temperature of the cured product tends to increase, and the CTE2/CTE1 tends to decrease; in addition, by using the thermal radical generator, the reliability tends to be improved; it is considered that this is because the use of thermal radical generator further promotes the polymerization of the polyfunctional (meth)acrylate compound.

From the comparison between Examples 12 and 13 and other Examples, by using the epoxy resin or a curing catalyst thereof, the tensile elongation rate tends to be improved; it is considered that this is because the polyamide resin and/or the polyimide resin is bonded (crosslinked) with the epoxy resin to form a cured film which is more stretchable and less likely to break.

From the comparison between Example 14 and other Examples, it is considered that the adhesion aid may act well with the presence of water, and the adhesiveness is improved.

On the other hand, the evaluation results of the photosensitive resin composition of Comparative Example 1, in which the E′₂₂₀ was less than 0.50 GPa, were inferior to the evaluation results of the photosensitive resin compositions of Examples 1 to 14.

### REFERENCE SIGNS LIST

10 sealing material
30 electrode pad
40 semiconductor chip
50 passivation film
60 insulating resin film (first insulating resin film)
70 insulating resin film (second insulating resin film)
80 solder bump
100 electronic device
110 conductive film
200 adhesive member
250 opening portion (first opening portion)
300 opening portion (second opening portion)

1. A photosensitive resin composition comprising:
a polyamide resin and/or a polyimide resin,
wherein, in a case where a cured film obtained by heating the photosensitive resin composition at 170° C. for 2 hours is subjected to a dynamic viscoelasticity measurement under the following conditions, a storage elastic modulus E′₂₂₀ at 220° C. is 0.5 to 3.0 GPa,
[conditions]
frequency: 1 Hz,
temperature: 30° C. to 300° C.,
heating rate: 5° C./min,
measurement mode: tensile mode.

2. The photosensitive resin composition according to claim 1,
wherein, in a case where a glass transition temperature of the cured film is denoted as Tg [° C.],
a coefficient of thermal expansion of the cured film in a temperature region from Tg−50[° C.] to Tg−20 [° C.] is denoted as CTE1, and a coefficient of thermal expansion of the cured film in a temperature region from Tg+20[° C.] to Tg+50[° C.] is denoted as CTE2, a value of CTE2/CTE1 is 1 to 10.

3. The photosensitive resin composition according to claim 1,
wherein the photosensitive resin composition contains a polyimide resin having an imide ring structure.

4. The photosensitive resin composition according to claim 1, further comprising:
a polyfunctional (meth)acrylate compound.

5. The photosensitive resin composition according to claim 1, further comprising:
a photosensitizing agent.

6. The photosensitive resin composition according to claim 5,
wherein the photosensitizing agent includes a photoradical generator.

7. The photosensitive resin composition according to claim 1, further comprising:
a thermal radical initiator.

8. The photosensitive resin composition according to claim 1, further comprising:
an epoxy resin.

9. The photosensitive resin composition according to claim 1,
wherein at least the polyamide resin and/or the polyimide resin is dissolved in a solvent to be in a form of a varnish.

10. The photosensitive resin composition according to claim 1,
wherein the photosensitive resin composition is used for forming an insulating layer in an electronic device.

11. A manufacturing method of an electronic device, comprising:
a film forming step of forming a photosensitive resin film over a substrate using the photosensitive resin composition according to claim 1;
an exposure step of exposing the photosensitive resin film; and
a development step of developing the exposed photosensitive resin film.

12. The manufacturing method of an electronic device according to claim 11, further comprising:
a thermosetting step of heating and curing the exposed photosensitive resin film after the development step.

13. An electronic device comprising:
a cured film of the photosensitive resin composition according to claim 1.
